(19) United States
(12) Patent Application Publication
(10) Pub. No.: US 2011/0221053 A1
(43) Pub. Date: Sep. 15, 2011

(54) PRE-PROCESSING TO REDUCE WAFER LEVEL WARPAGE

(75) Inventors: Arvind Chandrasekaran, San Diego, CA (US); Mark Nakamoto, San Diego, CA (US)

(73) Assignee: QUALCOMM INCORPORATED, San Diego, CA (US)

(21) Appl. No.: 12/688,500

(22) Filed: Mar. 11, 2010

(51) Int. Cl. H01L 25/065; H01L 21/70; H01L 21/78; H01L 23/52

(52) U.S. Cl. 257/686; 438/109; 438/113; 257/690; 257/723; 257/E25.013; 257/E21.599; 257/E23.141; 257/E21.532

(57) ABSTRACT

A method for packaging a stacked integrated circuit (IC) includes pre-processing the stacked IC before releasing the stacked IC from the carrier wafer. Pre-processing reduces wafer warpage and simplifies the packaging process by dicing materials separately. Pre-processing may be performed on the first tier wafer of a stacked IC during manufacturing to partially or completely dice the first tier wafer into first tier dies before release from the carrier wafer. Pre-processing may also be performed by laser cutting the mold compound surrounding the first tier wafer and second tier dies before releasing the stacked IC from the carrier wafer. Openings in the first tier wafer and/or mold compound allows balancing of stresses in the packaging process and reduction of wafer warpage.

### TECHNICAL FIELD

The present disclosure generally relates to integrated circuits. More specifically, the present disclosure relates to packaging integrated circuits.

### BACKGROUND

Semiconductor dies include collections of transistors and other components in an active layer of a substrate. Commonly, these substrates are semiconductor materials, and, in particular, silicon. Additionally, these substrates are conventionally thicker than necessary to obtain desirable device behavior. The semiconductor dies are singulated or diced from a semiconductor wafer.

Mold placed on the wafers have different stresses than the wafer resulting in unbalanced stress. As a result, the wafer may warp or bend to reach an equilibrium stress. Thick wafers are able to counterbalance the stress imposed by the mold better than thin wafers. Additionally, thick wafers have the robustness to withstand the dozens of processes, high temperatures, and transfers between tools or even fabrication sites.

However, thin wafers are employed, for example, in stacked ICs. Stacked ICs increase device functionality and decrease die size by stacking dies vertically. Similar to high-rise towers that fit more office space in a smaller land area, stacked ICs offer more space for transistors and other components while occupying the same area. Thin wafers are employed in stacked ICs to reduce the form factor of the stacked IC and to reduce the aspect ratio of some manufacturing processes. For example, etching of through vias is an aspect ratio limited process, which limits the thickness of the wafer. When handling a thin wafer a thicker carrier wafer is attached to provide mechanical support.

Manufacturing a stacked IC includes attaching a first tier wafer to a carrier wafer for support before thinning the first tier wafer. After thinning, second tier dies are placed on the first tier wafer, a mold compound is placed on the first tier wafer and second tier dies, and the first tier wafer is released from the carrier wafer. Once released from the carrier wafer, the first tier wafer may have an unbalanced stress between the wafer and the mold compound of the first tier wafer resulting in wafer warpage. The stress imbalance is due, in part, to thinning the first tier wafer such that the first tier wafer no longer provides sufficient support for the mold compound. That is, without support the first tier wafer is unable to resist the mechanical stress due to the mold compound.

A conventional group of stacked integrated circuits before carrier wafer release is illustrated in FIG. 1A. A stacked IC group 100 includes a first tier wafer 110 having film layers 112 coupled to a packaging connection 114. The first tier wafer 110 is attached to a carrier wafer 102 with adhesive 104. Second tier dies 120 are attached to a redistribution layer 116 on the first tier wafer 110 through interconnects 122. A mold compound 130 encapsulates the first tier wafer 110 and the second tier dies 120.

The stacked IC group 100 after release from the carrier wafer 102 is shown in FIG. 1B. After release from the carrier wafer 102, the first tier wafer 110 warps to balance stresses imposed by the mold compound 130. For example, in a 200 mm wafer the wafer warpage may exceed 10 mm measured from between the maximum and minimum height of the wafer when the wafer is placed with its face on a perfect plane. As a result of the warpage, devices in the first tier wafer 110 may become damaged and inoperative.

Conventional methods for reducing wafer warpage include selecting a mold compound having a coefficient of thermal expansion similar to the first tier wafer. However, these method have not significantly reduced wafer warpage.

Thus, there is a need for reduce wafer warpage during packaging processes.

### BRIEF SUMMARY

According to one aspect of the disclosure, a method for packaging a stacked integrated circuit includes attaching a carrier wafer to a first tier wafer. The method also includes coupling second tier dies to the first tier wafer to form a group of stacked integrated circuits after attaching the carrier wafer to the first tier wafer. The method further includes applying a mold compound to the second tier dies coupled to the first tier wafer after coupling the second tier dies to the first tier wafer. The method also includes pre-processing the group of stacked integrated circuits. The method further includes releasing the first tier wafer from the carrier wafer after pre-processing the group of stacked integrated circuits.

According to another aspect of the disclosure, an integrated circuit includes first tier dies stacked on a carrier wafer. The first tier dies are at least partially separated. The integrated circuit also includes second tier dies stacked on the first tier dies. The integrated circuit further includes a mold compound surrounding the first tier dies and surrounding the second tier dies. The mold compound fills spaces between the first tier dies.

According to a further aspect of the disclosure, a method for packaging a stacked integrated circuit includes the step of attaching a carrier wafer to a first tier wafer. The method also includes the step of coupling second tier dies to the first tier wafer to form a group of stacked integrated circuits after attaching the carrier wafer to the first tier wafer. The method further includes the step of pre-processing the group of stacked integrated circuits. The method also includes the step of releasing the first tier wafer from the carrier wafer after pre-processing the group of stacked integrated circuits.

According to another aspect of the disclosure, a stacked integrated circuit is manufactured by a process including attaching a carrier wafer to a first tier wafer. The process also includes coupling second tier dies to the first tier wafer to form a group of stacked integrated circuits, after attaching the carrier wafer to the first tier wafer. The process further includes pre-processing the group of stacked integrated circuits. The process also includes releasing the first tier wafer from the carrier wafer after pre-processing the group of stacked integrated circuits.

According to a further aspect of the disclosure, an integrated circuit includes a first tier wafer stacked on a carrier wafer. The first tier wafer includes means for separating the first tier wafer into first tier dies. The integrated circuit also includes second tier dies stacked on the first tier wafer. The first tier wafer further includes a mold compound surrounding the first tier dies and surrounding the second tier dies. The mold compound fills the separating means.

The foregoing has outlined rather broadly the features and technical advantages of the present disclosure in order that the detailed description that follows may be better understood. Additional features and advantages will be described hereinafter which form the subject of the claims of the disclosure. It should be appreciated by those skilled in the art that the conception and specific embodiments disclosed may be readily utilized as a basis for modifying or designing other structures for carrying out the same purposes of the present disclosure. It should also be realized by those skilled in the art that such equivalent constructions do not depart from the technology of the disclosure as set forth in the appended claims. The novel features which are believed to be characteristic of the disclosure, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1A is a cross-sectional view illustrating a conventional integrated circuit before carrier wafer release.

FIG. 1B is a cross-sectional view illustrating a conventional wafer after carrier wafer release.

FIG. 2A is a cross-sectional view illustrating an exemplary integrated circuit before carrier wafer release according to one embodiment.

FIG. 2B is a cross-sectional view illustrating an exemplary wafer after carrier wafer release according to one embodiment.

FIG. 3 is a flow chart illustrating an exemplary packaging process employing pre-processing according to one embodiment.

FIG. 4A-H are cross-sectional views illustrating an exemplary packaging process employing pre-processing according to one embodiment.

FIG. 5A is a cross-sectional view illustrating an exemplary wafer after dicing of the mold compound according to one embodiment.

FIG. 5B is a cross-sectional view illustrating an exemplary wafer after release of the carrier wafer according to one embodiment.

FIG. 5C is a cross-sectional view illustrating an exemplary wafer after dicing of the mold compound according to one embodiment.

FIG. 6 is a block diagram showing an exemplary wireless communication system in which an embodiment of the disclosure may be advantageously employed.

FIG. 7 is a block diagram illustrating a design workstation used for circuit, layout, and logic design of a semiconductor component according to one embodiment.

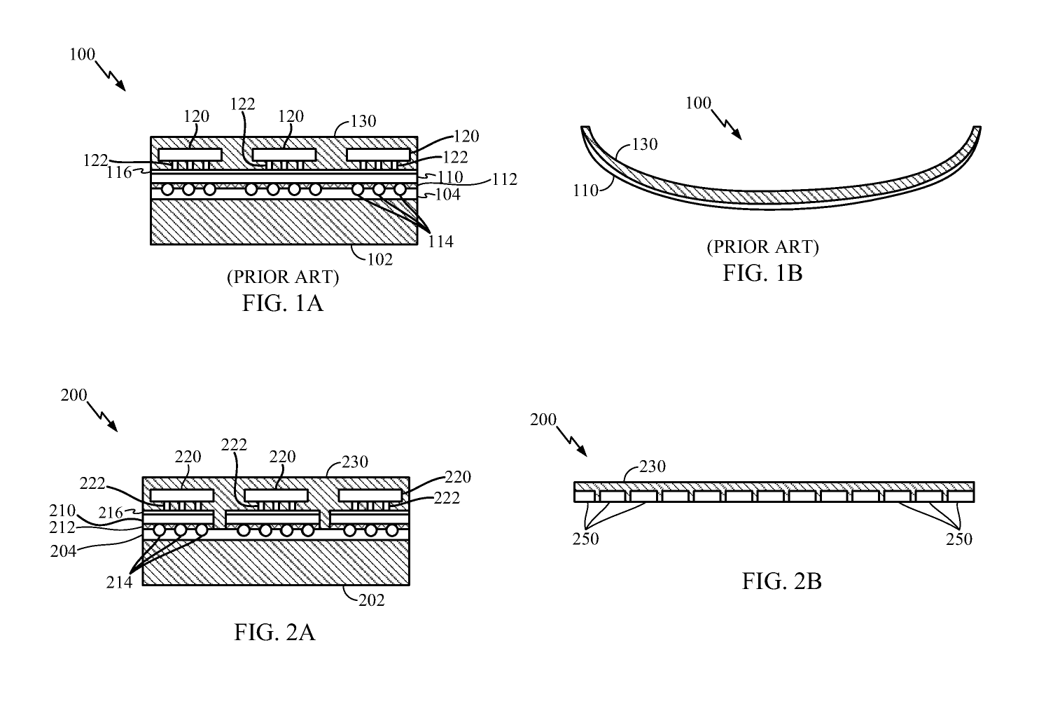

### DETAILED DESCRIPTION

One technique for reducing warpage while manufacturing stacked ICs during packaging is pre-processing the first tier wafer before carrier wafer release. Pre-processing the portions of the stacked IC before release of the carrier wafer allows the first tier wafers to expand or contract to alleviate stresses in the stacked IC. Additionally, pre-processing aids dicing into individual stacked ICs. According to one embodiment, pre-processing of the first tier wafer includes dicing into separate dies. With the first tier wafer already diced, dicing into individual stacked ICs involves cutting through only the mold compound. According to another embodiment, pre-processing includes partially dicing the first tier wafer to balance stress and reduce wafer warpage. In a further embodiment, pre-processing includes partially dicing the mold compound. In yet another embodiment, pre-processing includes a wafer-level etch of the first tier wafer. Where pre-processing includes a wafer-level etch of the first tier wafer, this technique of reducing warpage may be combined with either one of the previously mentioned techniques for reducing warpage.

FIG. 2A is a cross-sectional view illustrating an exemplary integrated circuit before carrier release according to one embodiment. A group 200 of stacked ICs includes first tier dies 210 having film layers 212 coupled to a packaging connection 214. The first tier dies 210 are attached to a carrier wafer 202 by an adhesive 204. Second tier dies 220 are coupled to a redistribution layer 216 of the first tier dies 210 by interconnects 222. A mold compound 230 encapsulates the stacked ICs.

According to one embodiment, the first tier dies 210 are diced from a first tier wafer before attachment of the second tier dies 220. Subsequently, application of the mold compound 230 fills in space between the first tier dies 210. After detachment from the carrier wafer 202, the space between the first tier dies 210 allows expansion or contraction of the first tier dies 210 to accommodate stresses in the stacked ICs.

FIG. 2B is a cross-sectional view illustrating an exemplary wafer after carrier wafer release according to one embodiment. The group 200 of stacked ICs includes pairs 250 of the first tier dies 210 and the second tier dies 220. The pairs 250 are separated by a small space and encapsulated in the mold compound 230. Warpage of the group 200 of stacked ICs is reduced by pre-dicing the first tier wafer into the first tier dies 210. Although pairs 250 are shown, the disclosure is not limited to such a configuration. For example, multiple second tier dies 220 could be stacked on a single first tier die 210.

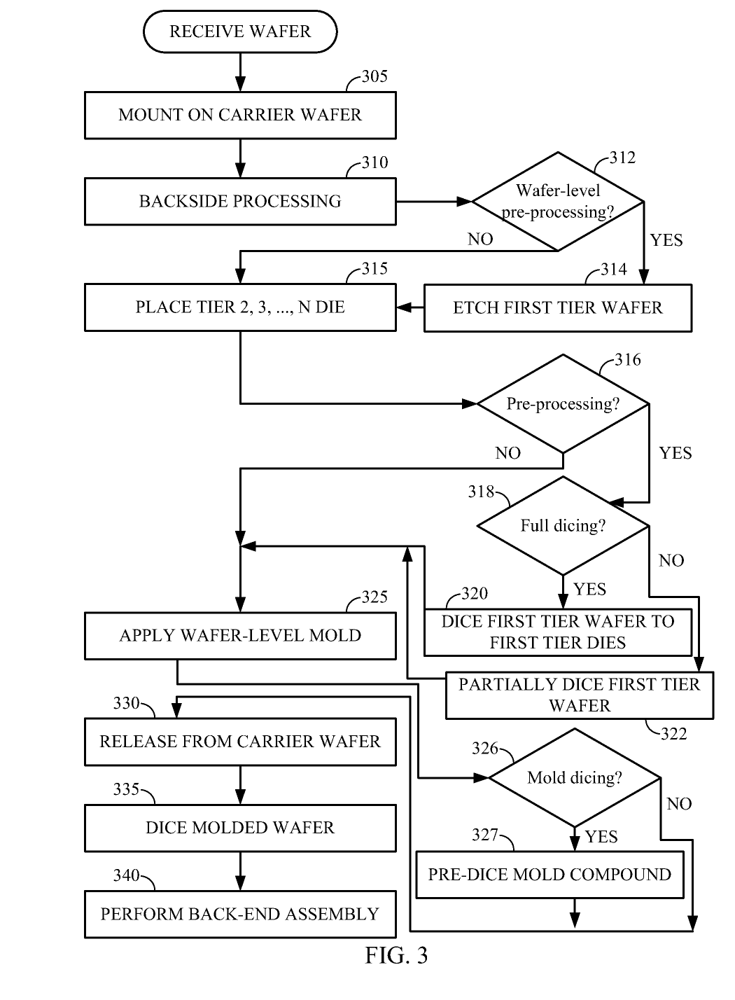

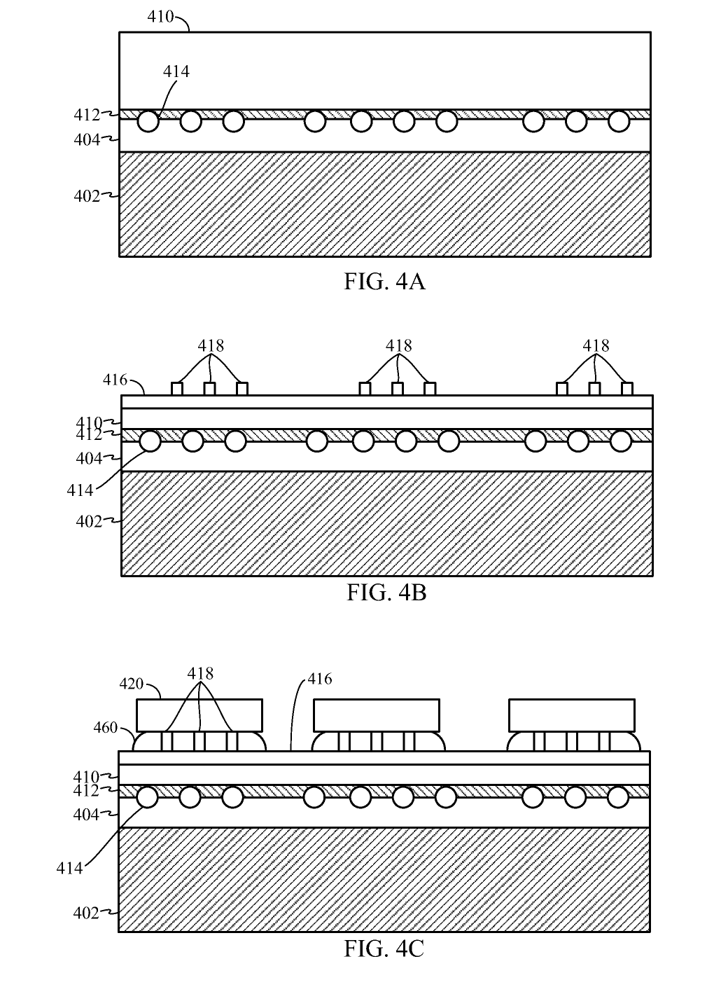

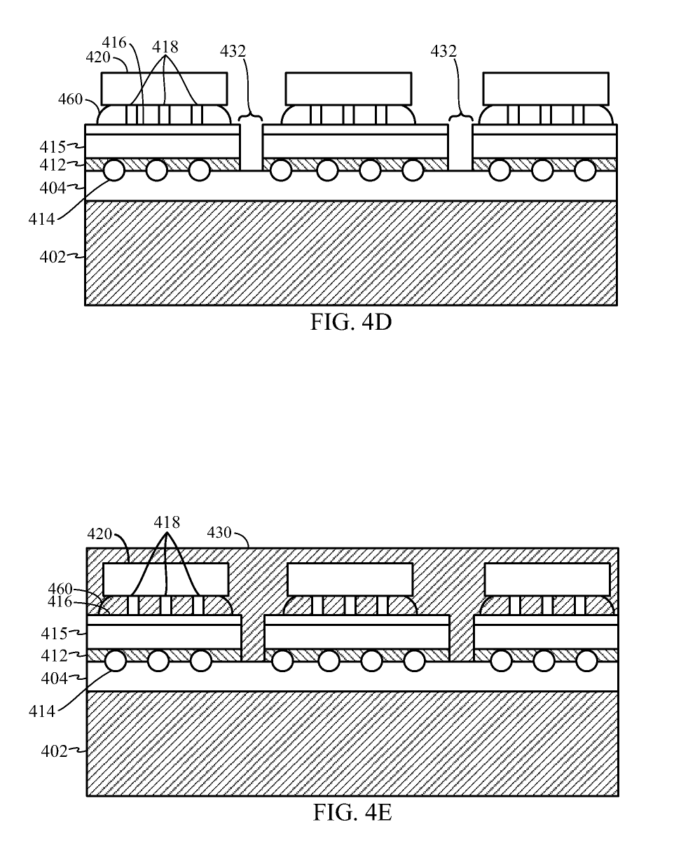

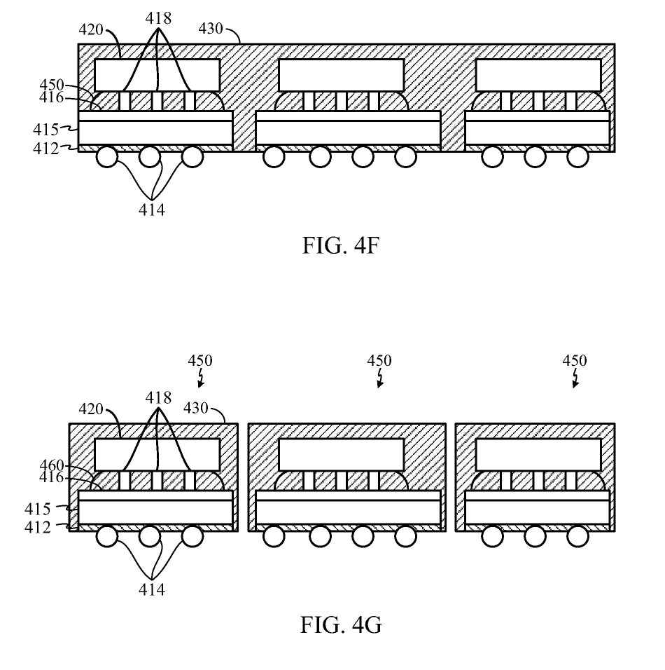

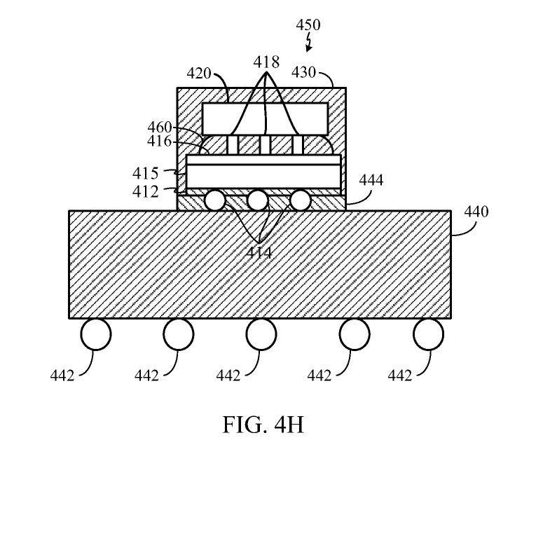

Turning to FIG. 3, a flow chart that illustrates an exemplary process for pre-processing according to one embodiment is shown. FIGS. 4A-H are cross-sectional views illustrating the exemplary process according to one embodiment.

At block 305 a first tier wafer is mounted on a carrier wafer. FIG. 4A illustrates an integrated circuit after attachment to a carrier wafer according to one embodiment. A first tier wafer 410 having film layers 412 is coupled to a packaging connection 414. The first tier wafer 410 may be, for example, a semiconductor material such as silicon or an insulating material such as glass. A carrier wafer 402 is attached to the first tier wafer 410 with an adhesive 404 (such as, for example, glue) or vacuum holding.

At block 310 backside processing of the first tier wafer is performed. Backside processing may include, for example, thinning, recess etching, microbumping, materials deposition, through via formation, redistribution layer formation, patterning, and passivation. FIG. 4B illustrates an integrated circuit after backside processing according to one embodiment. The first tier wafer 410 is thinned, and a redistribution layer 416 is formed on the first tier wafer 410. Additionally, interconnects 418, such as microbumps, are deposited on the redistribution layer 416. Although interconnects 418 are illustrated, the process may also be applied in die stacking processes such as direct face-to-face bonding without bumps. Although no through vias are shown, through vias may be present in the first tier wafer 410 to accommodate stacking. Additional die stacking processes may be used with pre-processing such as, for example, extended wafer-level fan-out processes.

At block 312 it is determined whether wafer level pre-processing will be performed. Wafer-level pre-processing reduces warpage by creating a discontinuity in the first tier wafer 410 to allow the first tier dies to expand or contract to alleviate stresses. If wafer level pre-processing is to be performed, lines are etched in the first tier wafer at block 314 and the process continues to block 315. The lines may, for example, match the dicing pattern used during later back-end assembly. The lines may be patterned according to known processes, such as, depositing a photoresist, patterning the photoresist, and etching the first tier wafer using the photoresist as a hard mask. As another example, a material may be deposited on the first tier wafer before deposition of the photoresist and act as a hard mask for patterning lines in the first tier wafer. The results of wafer level-pre-processing are not illustrated in FIGS. 4A-4H. If no wafer level pre-processing is determined to be performed at block 314, the process continues to block 315.

At block 315 second tier dies are placed on the first tier wafer. Second tier dies may include, for example, memory circuitry, logic circuitry, telecommunications circuitry, passive components, and active components. FIG. 4C illustrates an integrated circuit after attachment of second tier dies according to one embodiment. Second tier dies 420 are coupled to the first tier wafer 410 through interconnects 418. Additionally, an underfill 460 may be deposited around the interconnects 418.

At block 316 it is determined whether pre-processing will be performed. If pre-processing is not to be performed at this time (for example when wafer level pre-processing occurred at block 314), the process continues to block 325. If pre-processing is to be performed, the process continues to block 318 to decide if full dicing is to be performed. If full dicing is to be performed the process continues to block 320 to dice the first tier wafer into first tier dies. FIG. 4D illustrates an integrated circuit after pre-processing according to one embodiment. Dicing the first tier wafer 410 with, for example, laser dicing or a diamond saw creates spaces 432 between first tier dies 415. Pre-processing including full dicing of the first tier wafer 410 results in cutting through only one material simplifying the dicing process. A mold compound (not yet shown) is diced separate from the first tier wafer 410.

If full dicing is not performed the process continues to block 322 to partially dice the first tier wafer. Partial dicing through a fraction of the first tier wafer may be performed with a laser or mechanical saw. The remaining thickness of the first tier wafer may be diced in subsequent processing such as during or after the back-end assembly. A partially diced first tier wafer is not illustrated in FIGS. 4A-4H. After partial dicing at block 322 the process continues to block 325.

Alternatively at blocks 320, 322, partial or full dicing may be performed with dry and/or wet etching in replacement of or in combination with other dicing methods such as, for example, laser dicing and diamond sawing. In one embodiment, the etching parameters may be varied during the etch to create a non-uniform wall that allows a mold compound (deposited later) to lock to the first tier dies 415. For example, etching parameters such as gas pressures, electrode voltages, and/or etch rate may alter the shape of the wall of the first tier dies 415.

At block 325 a wafer level mold is applied, which fills in between first tier dies. FIG. 4E illustrates an integrated circuit after applying a mold compound according to one embodiment. A mold compound 430 is deposited to support the first tier dies 415 and the second tier dies 420. The mold compound 430 also fills in the spaces 432 to protect the sides of the first tier dies 415 during subsequent processing. According to one embodiment, the mold compound 430 is an epoxy combined with filler material.

At block 326 it is determined whether the mold compound 430 is to be pre-processed. If the mold compound 430 is not pre-processed, the process continues to block 330.

At block 330 the carrier wafer is released from the first tier dies. After carrier wafer release, the first tier wafer would warp to balance stresses with the mold compound. However, pre-processing assists in balancing stresses and reduces wafer warpage after release of the carrier wafer. FIG. 4F illustrates an integrated circuit after carrier wafer release according to one embodiment. The carrier wafer 402 is released from the first tier die 415 by dissolving the adhesive 404. In one embodiment, additional cleaning processes may be performed on the first tier die 415 to remove adhesive residue.

At block 335 the group of stacked ICs are diced/singulated, i.e. the mold compound is diced. FIG. 4G illustrates diced integrated circuits according to one embodiment. Dicing of the mold compound 430 results in separation of individual stacked ICs 450. In the embodiments calling for pre-dicing during pre-processing at block 320, dicing only cuts through one material to separate the stacked ICs 450. Cutting through a single material during dicing improves reliability by implementing a single set of parameters for dicing.

At block 340 back-end assembly is completed on the individual stacked ICs. For example, a pick-and-place process may be used for placing individual stacked ICs on packaging substrates. FIG. 4H illustrates a packaged stacked IC according to one embodiment. The stacked IC 450 is attached to a packaging substrate 440 through the packaging connection 414. According to one embodiment, an underfill 444 is applied to the first tier die 415. The packaging substrate 440 may also include a packaging connection 442. Additional processing may be performed on the stacked ICs 450 such as, for example, applying additional molding.

Alternatively or in addition to pre-processing of the first tier wafer, the mold compound may be pre-diced before demount from the carrier wafer 402. In the flowchart of FIG. 3, after applying the wafer-level mold at block 325, it is determined if mold compound dicing will be performed at block 326. If mold compound dicing is performed, the process continues to block 327. If mold compound dicing will not occur, the processing continues to block 330.

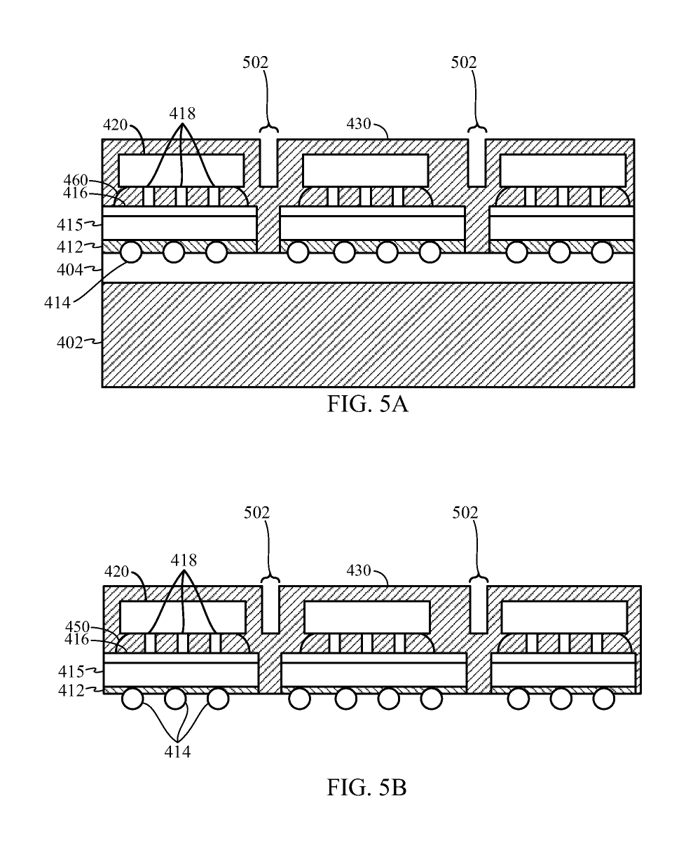

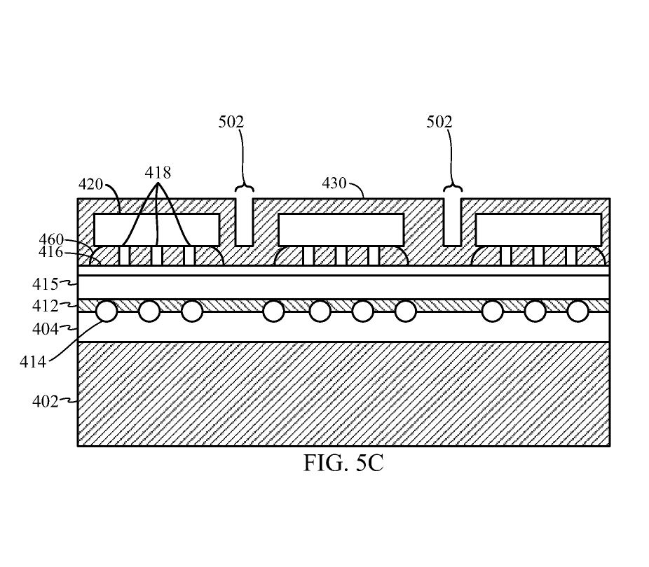

Referring to FIG. 5A, at block 327, the mold compound 430 is partially diced into openings 502. Dicing of the mold compound 430 may be performed, for example, by laser cutting. According to one embodiment, the openings 502 extend to the top of the first tier die 415 (although not depicted as such in the FIGURES). FIG. 5A illustrates a combination of pre-processing of the mold compound 430 and pre-processing of the first tier die 415.

According to another embodiment, the pre-processing of the mold compound 430 is performed without pre-processing of the first tier dies 415. Referring to FIG. 5C, a pre-processed mold compound 430 is illustrated without pre-processing of the first tier wafer 415.

After pre-processing the mold compound 430 at block 327, the process continues to block 330.

At block 330 the carrier wafer is released. Referring to FIG. 5B, the carrier wafer 402 is released from the first tier die 415 by dissolving the adhesive 404. In one embodiment, additional cleaning processes may be performed on the first tier die 415 to remove adhesive residue.

Processing on wafers with pre-processed mold compound as shown in FIGS. 5A and 5B continues to block 335 and is performed as illustrated in FIGS. 4G and 4H.

Pre-processing may be performed before and/or after placement of the tier two die. According to one embodiment, wafer-level pre-processing is performed to at least partially dice the first tier wafer before placement of tier two dies. According to another embodiment, pre-processing is performed after placement of the second tier die to at least partially dice the first tier wafer. According to yet another embodiment, pre-processing is performed after mold compound is applied to the first tier wafer and second tier dies to create openings in the mold compound. Any of the above mentioned embodiments may be combined.

Pre-processing a stacked IC during packaging processes before carrier wafer release reduces wafer warpage and improves wafer handling. The reduced wafer warpage increases reliability and increases assembly yield of the packaging process.

Additionally, in the embodiments completely dicing through the first tier wafer before molding, dicing of the ICs is separated into two dicing processes, each cutting through only a single material. Dicing of only one material improves reliability of the dicing process. Further, in some embodiments, pre-processing allows mold compound to encapsulate sides of the first tier dies for protection of the first tier die during subsequent processing.

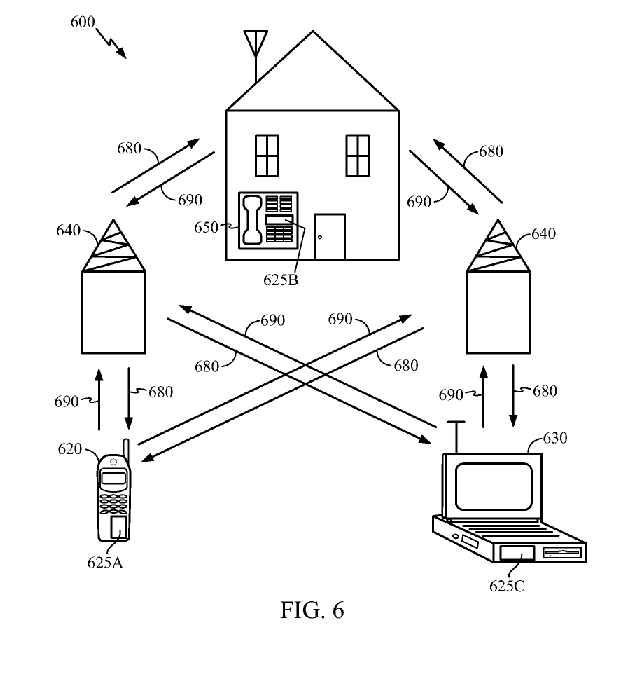

FIG. 6 shows an exemplary wireless communication system 600 in which an embodiment of the disclosure may be advantageously employed. For purposes of illustration, FIG. 6 shows three remote units 620, 630, and 650 and two base stations 640. It will be recognized that wireless communication systems may have many more remote units and base stations. Remote units 620, 630, and 650 include improved packaged ICs 625A, 625C, and 625B, respectively, which are embodiments as discussed further below. FIG. 6 shows forward link signals 680 from the base stations 640 and the remote units 620, 630, and 650 and reverse link signals 690 from the remote units 620, 630, and 650 to base stations 640.

In FIG. 6, remote unit 620 is shown as a mobile telephone, remote unit 630 is shown as a portable computer, and remote unit 650 is shown as a computer in a wireless local loop system. For example, the remote units may be cell phones, hand-held personal communication systems (PCS) units, portable data units such as personal data assistants, or fixed location data units such as meter reading equipment. Although FIG. 6 illustrates remote units according to the teachings of the disclosure, the disclosure is not limited to these exemplary illustrated units. The disclosure may be suitably employed in any device which includes packaged ICs.

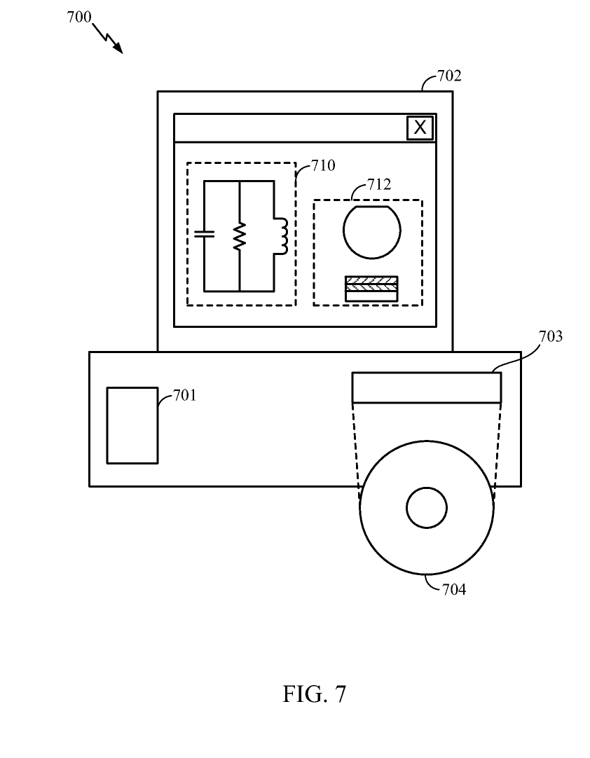

FIG. 7 is a block diagram illustrating a design workstation used for circuit, layout, and logic design of a semiconductor component as disclosed below. A design workstation 700 includes a hard disk 701 containing operating system software, support files, and design software such as Cadence or OrCAD. The design workstation 700 also includes a display to facilitate design of a circuit 710 or a semiconductor component 712 such as a wafer or die. A storage medium 704 is provided for tangibly storing the circuit design 710 or the semiconductor component 712. The circuit design 710 or the semiconductor component 712 may be stored on the storage medium 704 in a file format such as GDSII or GERBER. The storage medium 704 may be a CD-ROM, DVD, hard disk, flash memory, or other appropriate device. Furthermore, the design workstation 700 includes a drive apparatus 703 for accepting input from or writing output to the storage medium 704.

Data recorded on the storage medium 704 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 704 facilitates the design of the circuit design 710 or the semiconductor component 712 by decreasing the number of processes for designing semiconductor wafers.

The methodologies described herein may be implemented by various components depending upon the application. For example, these methodologies may be implemented in hardware, firmware, software, or any combination thereof. For a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, electronic devices, other electronic units designed to perform the functions described herein, or a combination thereof.

For a firmware and/or software implementation, the methodologies may be implemented with modules (e.g., procedures, functions, and so

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to store desired program code in the form of instructions or data structures and that can be accessed by a computer; disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the terminology “through silicon via” includes the word silicon, it is noted that through silicon vias are not necessarily constructed in silicon. Rather, the material can be any device substrate material.

Although the present disclosure and its advantages have been described in detail, it should be understood that various changes, substitutions and alterations can be made herein without departing from the technology of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A method for packaging a stacked integrated circuit, the method comprising:
attaching a carrier wafer to a first tier wafer;
coupling a plurality of second tier dies to the first tier wafer to form a group of stacked integrated circuits after attaching the carrier wafer to the first tier wafer;
applying a mold compound to the plurality of second tier dies coupled to the first tier wafer after coupling the plurality of second tier dies to the first tier wafer,
pre-processing the group of stacked integrated circuits; and
releasing the first tier wafer from the carrier wafer after pre-processing the group of stacked integrated circuits.

2. The method of claim 1, in which pre-processing is performed after coupling the plurality of second tier dies to the first tier wafer.

3. The method of claim 2, in which pre-processing comprises partially dicing the first tier wafer into a plurality of first tier dies.

4. The method of claim 2, in which pre-processing comprises fully dicing the first tier wafer into a plurality of first tier dies.

5. The method of claim 1, in which pre-processing is performed before coupling the plurality of second tier dies to the first tier wafer.

6. The method of claim 5, in which pre-processing comprises wafer-level etching of the first tier wafer into a plurality of first tier dies.

7. The method of claim 1, in which pre-processing is performed after applying the mold compound.

8. The method of claim 7, in which pre-processing comprises laser cutting the mold compound.

9. The method of claim 1, further comprising dicing the mold compound after releasing the first tier wafer from the carrier wafer.

10. The method of claim 1, further comprising:
performing backside processing after mounting the first tier wafer on the carrier wafer; and
performing back-end assembly after dicing the mold compound.

11. The method of claim 1, further comprising integrating the stacked integrated circuit into at least one of a mobile phone, a hand-held personal communication systems (PCS) unit, a portable data unit, and a fixed location data unit.

12. An integrated circuit, comprising:
a plurality of first tier dies stacked on a carrier wafer, the plurality of first tier dies at least partially separated;
a plurality of second tier dies stacked on the plurality of first tier dies; and
a mold compound surrounding the plurality of first tier dies and surrounding the plurality of second tier dies, the mold compound filling spaces between the plurality of first tier dies.

13. The integrated circuit of claim 12, in which the plurality of first tier dies are completely separated.

14. The integrated circuit of claim 12, in which the integrated circuit is integrated into at least one of a mobile phone, a hand-held personal communication systems (PCS) unit, a portable data unit, and a fixed location data unit.

15. A method for packaging a stacked integrated circuit, the method comprising the steps of:
attaching a carrier wafer to a first tier wafer;
coupling a plurality of second tier dies to the first tier wafer to form a group of stacked integrated circuits after attaching the carrier wafer to the first tier wafer;
pre-processing the group of stacked integrated circuits; and
releasing the first tier wafer from the carrier wafer after pre-processing the group of stacked integrated circuits.

16. The method of claim 15, further comprising integrating the stacked integrated circuit into at least one of a mobile phone, a hand-held personal communication systems (PCS) unit, a portable data unit, and a fixed location data unit.

17. A stacked integrated circuit manufactured by a process, comprising:
attaching a carrier wafer to a first tier wafer;
coupling a plurality of second tier dies to the first tier wafer to form a group of stacked integrated circuits after attaching the carrier wafer to the first tier wafer;
pre-processing the group of stacked integrated circuits; and
releasing the first tier wafer from the carrier wafer after pre-processing the group of stacked integrated circuits.

18. The stacked integrated circuit of claim 17, in which the stacked integrated circuit is integrated into at least one of a mobile phone, a hand-held personal communication systems (PCS) unit, a portable data unit, and a fixed location data unit.

19. An integrated circuit, comprising:
a first tier wafer stacked on a carrier wafer, the first tier wafer including means for separating the first tier wafer into a plurality of first tier dies;
a plurality of second tier dies stacked on the first tier wafer; and
a mold compound surrounding the plurality of first tier dies and surrounding the plurality of second tier dies, the mold compound filling the separating means.

20. The integrated circuit of claim 19, in which the integrated circuit is integrated into at least one of a mobile phone, a hand-held personal communication systems (PCS) unit, a portable data unit, and a fixed location data unit.
